(19) United States
(12) Patent Application Publication
(10) Pub. No.: US 2020/0282921 A1
(43) Pub. Date: Sep. 10, 2020

(54) SYSTEMS AND METHODS FOR LOW LIGHT VISION THROUGH PULSED LIGHTING

(71) Applicant: Ford Global Technologies, LLC, Dearborn, MI (US)

(72) Inventor: David Michael Herman, Oak Park, MI (US)

(21) Appl. No.: 16/297,228

(22) Filed: Mar. 8, 2019

(51) Int. Cl. B60R 11/04; H04N 5/374; H04N 5/235; H01L 27/092; H04N 5/232

(52) U.S. Cl. CPC B60R 11/04; H04N 5/374; H04N 5/232; H01L 27/0922; H04N 5/2353

(57) ABSTRACT

Vehicles and methods are described for improved vehicle camera functionality. An example vehicle includes a CMOS camera, lights, and an imaging controller. The imaging controller is configured to capture a plurality of image frames by, for each image frame: exposing one or more rows of the CMOS camera at a time, and pausing exposure during a frame time gap after capturing a last row of the CMOS camera. The imaging controller is also configured to, for one or more of the plurality of image frames: operate the one or more lights at a reduced intensity level during a first section of the image frame, wherein the reduced intensity level is lower than a maximum average intensity level; and operate the one or more lights at an increased intensity level during a second section of the image frame, wherein the increased intensity level is higher than the maximum average intensity level.

### TECHNICAL FIELD

The present disclosure generally relates to vehicle cameras and, more specifically, improved operation in low light conditions by pulsing lighting during use of camera having a rolling shutter.

### BACKGROUND

Modern vehicles include various cameras, such as forward facing, rear facing, and side facing cameras. One or more of these cameras can be used to assist the vehicle in performing various operations, such as autonomous control of the vehicle, automatic stopping or turning of the vehicle to avoid accidents, alerting a driver when an object is near the vehicle, and for various other purposes. During the day, these cameras generally have limited difficulty capturing images and resolving objects in the images at significant distances. However, in low light scenarios, the effective range of the cameras and/or systems that make use of the camera images (e.g., object detection) is significantly reduced.

Some of these cameras may be CMOS cameras operating using a rolling shutter, such that a subset of rows of the camera are exposed at a time from top to bottom (or bottom to top). The resulting image captured by the camera is then generated based on a combination of the exposed rows.

### SUMMARY

The appended claims define this application. The present disclosure summarizes aspects of the embodiments and should not be used to limit the claims. Other implementations are contemplated in accordance with the techniques described herein, as will be apparent to one having ordinary skill in the art upon examination of the following drawings and detailed description, and these implementations are intended to be within the scope of this application.

A vehicle is disclosed a CMOS camera including a plurality of rows, one or more lights configured to illuminate a field of view of the CMOS camera, and an imaging controller. The imaging controller is configured to capture a plurality of image frames by, for each image frame: exposing one or more rows of the CMOS camera at a time, and pausing exposure during a frame time gap after capturing a last row of the CMOS camera. The time frame gap may also include transfer time. The imaging controller is also configured to, for one or more of the plurality of image frames, operate the one or more lights at a reduced intensity level during a first section of the image frame, wherein the reduced intensity level is lower than a maximum average intensity level, and operate the one or more lights at an increased intensity level during a second section of the image frame, wherein the increased intensity level is higher than the maximum average intensity level.

A method of capturing images by a vehicle camera is disclosed. The method includes capturing a plurality of image frames by, for each image frame: exposing one or more rows of a CMOS camera at a time, and pausing exposure during a frame time gap after capturing a last row of the camera. The method also includes, for one or more of the plurality of image frames: operating one or more vehicle lights illuminating a field of view of the CMOS camera at a reduced intensity level during a first section of the image frame, wherein the reduced intensity level is lower than a maximum average intensity level, and operating the one or more vehicle lights at an increased intensity level during a second section of the image frame, wherein the increased intensity level is higher than the maximum average intensity level.

### BRIEF DESCRIPTION OF THE DRAWINGS

For a better understanding of the invention, reference may be made to embodiments shown in the following drawings. The components in the drawings are not necessarily to scale and related elements may be omitted, or in some instances proportions may have been exaggerated, so as to emphasize and clearly illustrate the novel features described herein. In addition, system components can be variously arranged, as known in the art. Further, in the drawings, like reference numerals designate corresponding parts throughout the several views.

FIG. 1 illustrates a vehicle according to embodiments of the present disclosure.

FIG. 2 illustrates a block diagram illustrating example electronic components of the vehicle of FIG. 1, according to embodiments of the present disclosure.

FIG. 3 illustrates an example series of image frames according to embodiments of the present disclosure.

FIG. 4 illustrates a further example of an image frame according to embodiments of the present disclosure.

FIG. 5 illustrates a flow chart of an example method according to embodiments of the present disclosure.

### DETAILED DESCRIPTION OF EXAMPLE EMBODIMENTS

While the invention may be embodied in various forms, there are shown in the drawings, and will hereinafter be described, some exemplary and non-limiting embodiments, with the understanding that the present disclosure is to be considered an exemplification of the invention and is not intended to limit the invention to the specific embodiments illustrated.

As noted above, vehicles may include one or more cameras used for various purposes, such as advanced driver assistance systems (ADAS) which may control or alert the user based on images captured by the cameras. One or more of these cameras may be a CMOS rolling shutter camera. Conventional sensors used in these cameras can have poor dynamic range and low light sensitivity. As a result, the ADAS functionality may be limited under certain circumstances such as at dusk, dawn, at night, and in other low light situation. Specifically, a camera's ability to detect objects at far range, and particularly to detect unreflective objects (e.g., a dark animal or pedestrian in dark clothing crossing the street) is limited under low light conditions.

Furthermore, the detection of objects in low light conditions may be limited to where the vehicle or other light sources (e.g., street lights) illuminate, and by the desire to avoid blinding other drivers with high beams. For example, under normal and even high beam lighting by a vehicle, the field of view of illumination may be smaller than the field of view of a camera (in typical daylight conditions). If not externally lit by another vehicle or infrastructure, objects inside the camera field of view but outside the typical lighting of the vehicle may remain undetected.

Some solutions can include increasing a sensor die size and expanding the pixel dimension of the camera, using an infrared camera, or utilizing specialized camera sensors, using multi-frame HDR, and using multi-gain single imaging HDR. These solutions, however, can significantly increase the cost and complexity of a vehicle, as well as having their own drawbacks and limitations.

With these issues in mind, example embodiments disclosed herein may enable a vehicle to image objects at further distances and image objects outside an illumination region of the vehicle headlights (such as towards the sides of the vehicle and towards the air to image signage above the roadway). Other benefits may include limited cost increase, and improving vehicle ADAS functionality.

In order to provide one or more of these benefits, example embodiments may include shifting illumination from a first section of an image frame capture to a second section. Regulations dictate that vehicle headlights must be positioned between a minimum and maximum height, must be angled so as to avoid shining into other drivers eyes, and are limited to a maximum output. In order to improve the lighting conditions of an image frame capture of the camera, the light output may be reduced during a period of time when the image is not capturing vital information (or is not capturing information at all), and increased when vital or important information is being captured.

In addition, examples may include introducing a pulse of light that is much greater than an average output (e.g., 10× greater) for a short duration corresponding to the time frame at which a desired row or rows are under exposure in the camera sensor. This can substantially increase the distance at which the camera can image for one or more rows, while not interfering with other drivers. The particular rows during capture of an image frame for which the lighting is increased can be selected based on a number of factors, including the vehicle location, orientation, elevation, knowledge about the vehicle surroundings, and more. This can allow the vehicle to better capture and detect the presence of objects surrounding the vehicle, signage, and provide various other benefits to the vehicle.

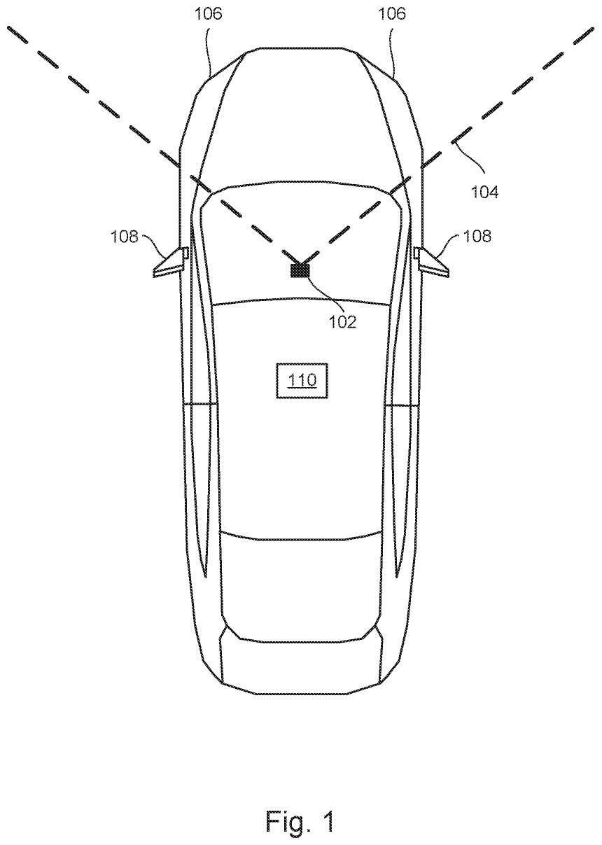

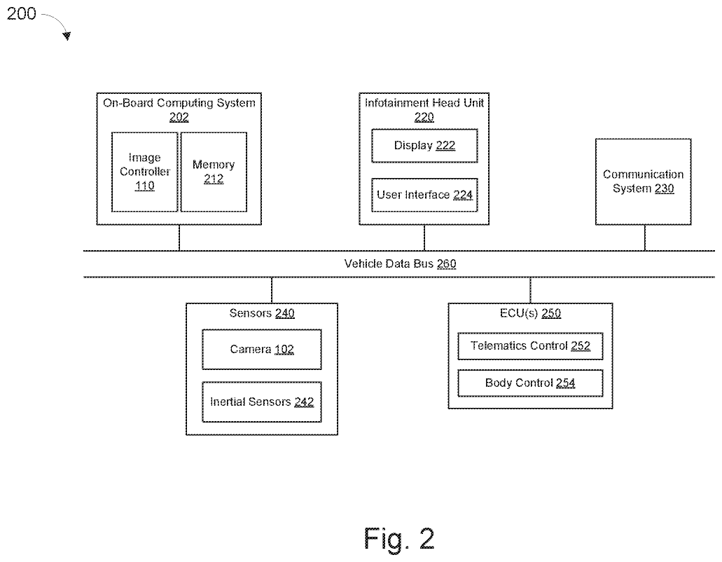

FIG. 1 illustrates an example vehicle 100 according to embodiments of the present disclosure. Vehicle 100 may be a standard gasoline powered vehicle, a hybrid vehicle, an electric vehicle, a fuel cell vehicle, or any other mobility implement type of vehicle. Vehicle 100 may be non-autonomous, semi-autonomous, or autonomous. Vehicle 100 may include parts related to mobility, such as a powertrain with an engine, a transmission, a suspension, a driveshaft, and/or wheels, etc. In the illustrated example, vehicle 100 may include one or more electronic components. Vehicle 100 may include a camera 102, headlights 106, side lights 108, and an imaging controller 110. Various other electronic components of vehicle 100 are described with reference to FIG. 2.

The camera 102 may be any suitable camera for capturing images. Camera 102 may be mounted such that it has a forward facing field of view 104, as shown in FIG. 1. Images capturing by the camera 102 may be displayed on vehicle display (not shown). Alternatively or additionally, images captured by the camera may be used by one or more vehicle systems, such as for object recognition, lane detection, autonomous control, and more.

Camera 102 may be a CMOS camera having a rolling shutter. To operate, the camera may expose rows from top to bottom, bottom to top, or in some other order. Each row may be exposed for a duration of time during the capture of an image frame. The exposure time for adjacent rows may overlap. Exposure may be paused during a frame time gap after the exposure of a last row of the camera 102, such that the camera 102 captures a specific number of frames per second (e.g., 30 fps).

One or more of the headlights 106 and side lights 108 may be configured to illuminate all or a portion of the field of view 104 of the camera 102. Each light may be an LED illuminator, having a relatively quick rise and fall time. This can enable the lights to operate such that one or more rows of the camera 102 are exposed to an increased light intensity, while one or more other rows are exposed to a reduced light intensity from the lights 106 and/or 108. Vehicle 100 may include additional lights on the side, front, top, bottom, and/or rear.

Imaging controller 110 may be configured to carry out one or more functions or actions described herein. For example, imaging controller 110 may be configured to capture a plurality of image frames via the camera 102 by exposing rows of the camera 102 in sequence. Imaging controller 110 may then pause exposure during a frame time gap between the exposure of last row for a given frame and the exposure of first row for a next frame.

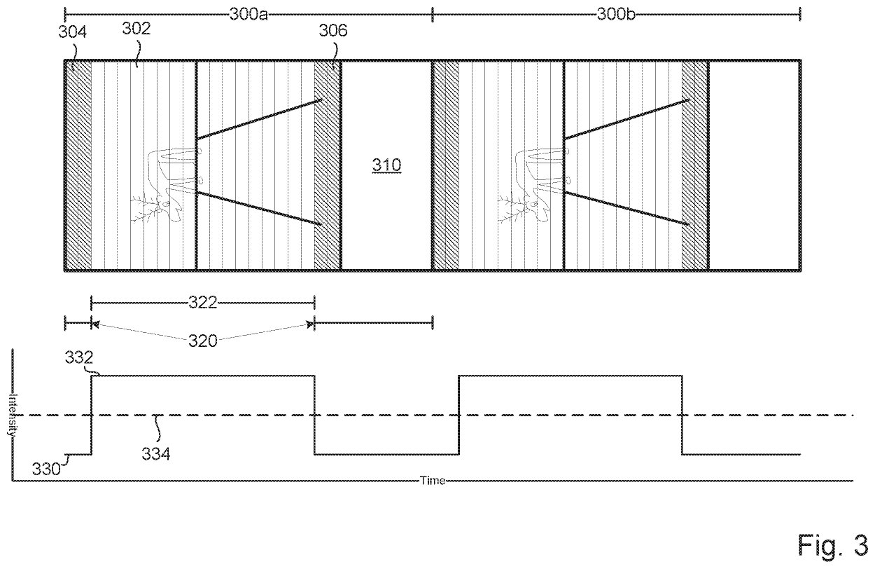

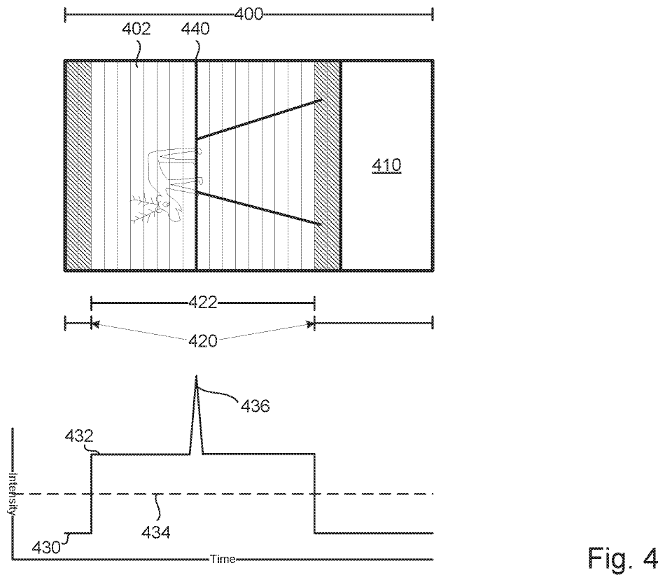

Imaging controller 110 may also be configured to control illumination of the lights 106 and 108 during exposure of the rows of the camera and during the frame time gap. This can include increasing and/or decreasing the illumination levels at specific times, based on one or more factors discussed below. The timing of when an increase or decrease occurs can be based on which row(s) are selected. For example, one or more rows may be selected based on various vehicle metrics, such as a geographic location, position, orientation, elevation, whether the vehicle is approaching signage, and more. Further specifics are discussed below with respect to FIGS. 3 and 4.

FIG. 2 illustrates an example block diagram 200 showing electronic components of vehicle 100, according to some embodiments. In the illustrated example, the electronic components 200 include an on-board computing system 202, an infotainment head unit 220, a communication system 230, sensors 240, electronic control unit(s) 250, and vehicle data bus 260.

The on-board computing system 202 may include the image controller 110, which may include a microcontroller unit, controller or processor, and memory 212. The controller 110 may be any suitable processing device or set of processing devices such as, but not limited to, a microprocessor, a microcontroller-based platform, an integrated circuit, one or more field programmable gate arrays (FPGAs), and/or one or more application-specific integrated circuits (ASICs). The memory 212 may be volatile memory (e.g., RAM including non-volatile RAM, magnetic RAM, ferroelectric RAM, etc.), non-volatile memory (e.g., disk memory, FLASH memory, EPROMs, EEPROMs, memristor-based non-volatile solid-state memory, etc.), unalterable memory (e.g., EPROMs), read-only memory, and/or high-capacity storage devices (e.g., hard drives, solid state drives, etc.). In some examples, the memory 212 includes multiple kinds of memory, particularly volatile memory and non-volatile memory.

The memory 212 may be a non-transitory computer-readable media on which one or more sets of instructions, such as the software for operating the methods of the present disclosure, can be embedded. The instructions may embody one or more of the methods or logic as described herein. For example, the instructions reside completely, or at least partially, within any one or more of the memory 212, the computer-readable medium, and/or within the imaging controller 110 during execution of the instructions.

The terms “non-transitory computer-readable medium” and “computer-readable medium” include a single medium or multiple media, such as a centralized or distributed database, and/or associated caches and servers that store one or more sets of instructions. Further, the terms “non-transitory computer-readable medium” and “computer-readable medium” include any tangible medium that is capable of storing, encoding or carrying a set of instructions for execution by a processor or that cause a system to perform any one or more of the methods or operations disclosed herein. As used herein, the term “computer readable medium” is expressly defined to include any type of computer readable storage device and/or storage disk and to exclude propagating signals.

The infotainment head unit 220 may provide an interface between vehicle 100 and a user. The infotainment head unit 220 may include one or more input and/or output devices, such as display 222 and user interface 224, to receive input from and display information for the user(s). The input devices may include, for example, a control knob, an instrument panel, a digital camera for image capture and/or visual command recognition, a touch screen, an audio input device (e.g., cabin microphone), buttons, or a touchpad. The output devices may include instrument cluster outputs (e.g., dials, lighting devices), actuators, a head-up display, a center console display (e.g., a liquid crystal display (LCD), an organic light emitting diode (OLED) display, a flat panel display, a solid state display, etc.), and/or speakers. In the illustrated example, the infotainment head unit 220 includes hardware (e.g., a processor or controller, memory, storage, etc.) and software (e.g., an operating system, etc.) for an infotainment system (such as SYNC® and MyFord Touch® by Ford®, Entune® by Toyota®, IntelliLink® by GMC®, etc.). In some examples the infotainment head unit 220 may share a processor with on-board computing system 202. Additionally, the infotainment head unit 220 may display the infotainment system on, for example, a center console display of vehicle 100.

Communications system 230 may include wired or wireless network interfaces to enable communication with one or more internal or external systems, devices, or networks. Communications system 230 may also include hardware (e.g., processors, memory, storage, etc.) and software to control the wired or wireless network interfaces. In the illustrated example, communications system 230 may include a Bluetooth® module, a GPS receiver, a dedicated short range communication (DSRC) module, an Ultra-Wide Band (UWB) communications module, a WLAN module, and/or a cellular modem, all electrically coupled to one or more respective antennas.

The cellular modem may include controllers for standards-based networks (e.g., Global System for Mobile Communications (GSM), Universal Mobile Telecommunications System (UMTS), Long Term Evolution (LTE), Code Division Multiple Access (CDMA), WiMAX (IEEE 802.16m); and Wireless Gigabit (IEEE 802.11ad), etc.). The WLAN module may include one or more controllers for wireless local area networks such as a Wi-Fi® controller (including IEEE 802.11 a/b/g/n/ac or others), a Bluetooth® controller (based on the Bluetooth® Core Specification maintained by the Bluetooth® Special Interest Group), and/or a ZigBee® controller (IEEE 802.15.4), and/or a Near Field Communication (NFC) controller, etc. Further, the internal and/or external network(s) may be public networks, such as the Internet; a private network, such as an intranet; or combinations thereof, and may utilize a variety of networking protocols now available or later developed including, but not limited to, TCP/IP-based networking protocols.

Communications system 230 may also include a wired or wireless interface to enable direct communication with an electronic device (such as a mobile device of a user). An example DSRC module may include radio(s) and software to broadcast messages and to establish direct connections between vehicles and between vehicles and one or more other devices or systems. DSRC is a wireless communication protocol or system, mainly meant for transportation, operating in a 5.9 GHz spectrum band.

Sensors 240 may be arranged in and around vehicle 100 in any suitable fashion. Sensors 240 may include the camera 102, and one or more inertial sensors 242. The inertial sensors 242 may provide information about the vehicle heading, orientation, and more.

The ECUs 250 may monitor and control subsystems of vehicle 100. ECUs 250 may communicate and exchange information via vehicle data bus 260. Additionally, ECUs 250 may communicate properties (such as, status of the ECU 250, sensor readings, control state, error and diagnostic codes, etc.) to and/or receive requests from other ECUs 250. Some vehicles may have seventy or more ECUs 250 located in various locations around the vehicle communicatively coupled by vehicle data bus 260. ECUs 250 may be discrete sets of electronics that include their own circuit(s) (such as integrated circuits, microprocessors, memory, storage, etc.) and firmware, sensors, actuators, and/or mounting hardware. In the illustrated example, ECUs 250 may include the telematics control unit 252 and the body control unit 254.

The telematics control unit 252 may control tracking of the vehicle 100, for example, using data received by a GPS receiver, communication system 230, and/or one or more sensors 240. The body control unit 254 may control various subsystems of the vehicle. For example, the body control unit 254 may control a trunk latch, windows, power locks, power moon roof control, an immobilizer system, and/or power mirrors, etc.

Vehicle data bus 260 may include one or more data buses, in conjunction with a gateway module, that communicatively couple the on-board computing system 202, infotainment head unit 220, communications module 230, sensors 240, ECUs 250, and other devices or systems connected to the vehicle data bus 260. In some examples, vehicle data bus 260 may be implemented in accordance with the controller area network (CAN) bus protocol as defined by International Standards Organization (ISO) 11898-1. Alternatively, in some examples, vehicle data bus 260 may be a Media Oriented Systems Transport (MOST) bus, or a CAN flexible data (CAN-FD) bus (ISO 11898-7) or a combination of CAN and CAN-FD.

FIG. 3 illustrates an example series of image frames 300a and 300b, according to embodiments of the present disclosure. Image frames 300a and 300b may be similar or identical to each other.

Image frame 300a includes a plurality of rows 302. Each row may include a plurality of pixels. Image frame 300a also includes a frame time gap 310. The frame time gap 310 may comprise a large or small percentage of the overall image frame 300. For example, the frame time gap may comprise between 15-40% of the overall frame. The frame time gap duration may be determined or set based on a frame rate at which the camera operates. For example, the camera 102 may increase or decrease the frame time gap in order to produce a particular number of frames per second, such as 30 fps, and account for different required exposure times during day and night lighting conditions. Other frame rates can be used as well.

Imaging controller 110 may also be configured to capture a plurality of image frames by exposing rows of the CMOS camera 102 and pausing exposure during the frame time gap 310 after exposure of the last row 306.

Imaging controller may also be configured to, for one or more frames, operate the one or more lights at a reduced intensity level during a first section of the image frame, wherein the reduced intensity level is lower than a maximum average intensity level; and operate the one or more lights at an increased intensity level during a second section of the image frame, wherein the increased intensity level is higher than the maximum average intensity level.

In the example shown in FIG. 3, the first section 320 and second section 322 of the image frame 300a are shown. The light intensity level during the first section 320 is reduced 330 with respect to the maximum average intensity level, and the light intensity level during the second section 322 is increased 332 with respect to the maximum average intensity level. In some examples, the combined average intensity level of the reduced intensity level during the first section 320 and the increased intensity level during the second section 322 is the maximum average intensity level 334. This enables the vehicle to maintain an overall light intensity output that remains at or below the maximum allowed output.

In some examples, a difference between the reduced light intensity level 330 and the increased light intensity level 332 is 5%. Various studies have shown that this level of “flicker” or change in intensity is within the range at which a typical human does not notice. However if the change in intensity is larger than 5%, there may be a risk of annoying or harming other drivers. Additionally, a short pulse duration may be required to account for flicker or eye safety effects causing problems for other drivers. The maximum average intensity level 334 may be dictated by one or more regulations, as noted above.

Various disclosed embodiments thus cause a shift of illumination from the first section 320 to the second section 322. This has a two-fold benefit—keeping the average output light intensity level at or below the allowed maximum, and not causing any relevant information to be lost by lowering lighting during capture of critical rows of the camera. During exposure of rows in the first section 320, the camera 102 does not capture important information (i.e., the frame time gap 310 includes no relevant visual data), but the camera 102 does capture relevant information for the driver and/or vehicle systems during the second section 322.

In a particular example, the first section 320 includes the frame time gap 310. Because the camera 102 does not capture relevant visual information during the frame time gap 310, illumination is not needed by the camera (although illumination is still helpful for a driver during this time period). Thus, regarding the camera's functionality, there is no drawback to reducing the illumination during the frame time gap 310.

In another example, the first section 320 may also or alternatively include a subset of the plurality of rows 302 of the image frame 300, including either or both of the top row 304 and the bottom row 306. The top roe 304 and bottom row 306 of the camera may capture a shroud of the camera, and as such these rows do not capture relevant visual information for use by the driver and/or vehicle systems. The top row 304 and bottom row 306 may capture the same information in every frame because they are covered by the shroud.

In some examples, the second section 322 includes one or more of the plurality of rows 302 of the camera—particularly those rows that include relevant visual information (e.g., objects, signage, the horizon, etc.). For example, the second section may include all rows 302 of the camera. In this case, the first section may comprise the frame time gap 310, while the second section comprises all rows of the camera.

In another example, the second section can include a subset of the plurality of rows 302. This scenario is shown in FIG. 3, wherein the first section 320 includes the frame time gap 310 and the rows covered by the shroud, while the second section 322 comprises rows that are not covered by the shroud.

FIG. 4 illustrates a further example image frame 400 according to embodiments of the present disclosure. In particular, FIG. 4 illustrates an increased light pulse 436 during the second section 422. Frame 400 includes a plurality of rows 402, and a frame time gap 410.

The imaging controller 110 may reduce a lighting intensity level 430 during the first section 420, and increase the lighting intensity level 432 during the second section 422. As shown, the second section 422 also includes a subsection during which the light intensity level is increased significantly (e.g., 10×), shown as the peak 436 in FIG. 4. The light intensity peak 436 may be at any position within the second section 422. Further, the second section 422 may not include an increased light intensity level, except for the peak 436. In other words, the light intensity level may be below the maximum average light intensity level 434 during the capture of all frames and the frame time gap, except for those frames that occur during the peak 436. It should be appreciated that the second section 422 may include both the peak and one or more surrounding rows (such as is shown in FIG. 4), or may alternatively include only the portion/rows including the peak 436.

Image frame 400 shows a horizon 440, along which an animal is seen (a moose). Various embodiments may include selecting one or more rows for the second section 422 based on the position of the horizon 440, including the vertical position and/or the particular rows that surround the horizon. For example, the imaging controller may determine the position of the horizon 440, and select one or more rows proximate the horizon 440. These selected rows may then comprise the second section, for which the light intensity level is increased. Rows proximate the horizon 440 may be selected because the horizon 440 has a high likelihood of containing an object for detection by the vehicle (e.g., animals, people walking across the street, etc.).

In certain examples, the imaging controller 110 may select one or more rows for the second section 422 based on one or more vehicle metrics. The vehicle metrics may include a geographic location, vehicle position, orientation, elevation, vehicle inertial characteristics, and whether the vehicle is approaching signage (determined, for example, based on GPS and map data). These vehicle metrics can be used to determine which rows to include in the second section 422. For example, rows including signage may be selected. Rows predicted to include signage may be includes (e.g., based on a predicted route of the vehicle, among other information). Rows including or surrounding the horizon may be selected. Predictive algorithms may be used to determine where the horizon 440 and/or signage is likely to be located based on the vehicle position, movement, and other metrics disclosed herein. These predicted row locations of the relevant visual information may impact the selection of rows for the second section 422. Various other metrics and determinations can be used as well.

In one example, the imaging controller 110 may predict that overhead signage is approaching. In response, the imaging controller may select one or more rows toward a top of the image frame 440. When these selected rows are exposed during capture of an image frame, the lights may be controlled to have an increased intensity level. In addition, one or more additional lights may be turned on (such as the high beams, side lights, or more). As a result, the rows of the second section may receive additional light reflected back off the signage, allowing the vehicle to detect the signage at a greater distance.

In another example, the imaging controller 110 may determine the position of the horizon 440 with respect to the camera rows (e.g., determine which rows include the horizon). This may be determined or predicted based on the vehicle metrics such as whether the vehicle is going uphill, downhill, or along a flat surface. Further, the vehicle may predict the upcoming terrain of the vehicle based on the geographic location, planned route, past image frames, and more. Once the horizon 440 is determined or predicted, the rows surrounding the horizon may be selected for the second section, so as to provide increased lighting while those rows are exposed. This can enable the vehicle to detect objects on the horizon at an increased distance.

In some examples, the imaging controller 110 may modify a gain and/or exposure time of one or more rows. This can include, for example, the rows that are selected for inclusion in the second section.

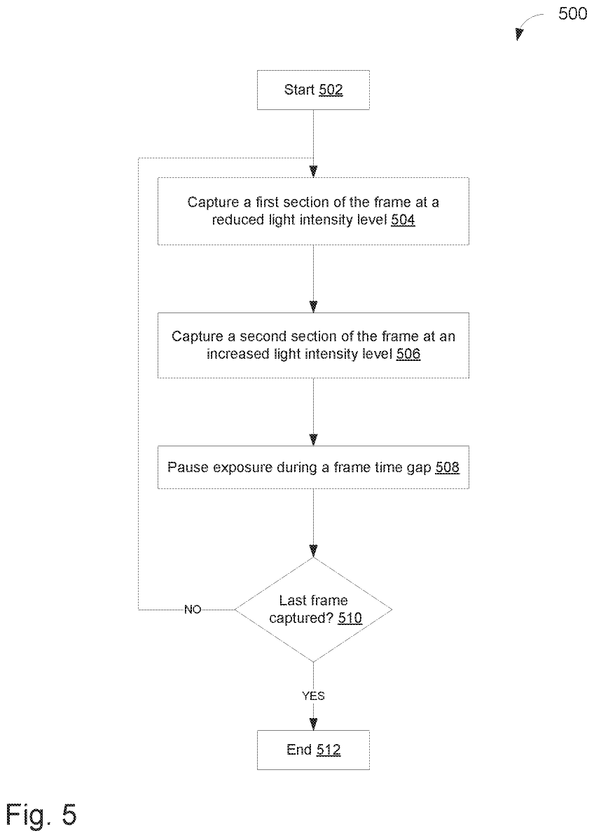

FIG. 5 illustrates a flowchart of an example method 500 according to embodiments of the present disclosure. Method 500 may enable a vehicle camera vision system to detect objects at greater distances, and with improved clarity, by shifting light intensity from a first section to a second section during capture of an image frame. The flowchart of FIG. 5 is representative of machine readable instructions that are stored in memory (such as memory 212) and may include one or more programs which, when executed by a processor (such as imaging controller 110) may cause vehicle 100 to carry out one or more functions described herein. While the example program is described with reference to the flowchart illustrated in FIG. 5, many other methods for carrying out the functions described herein may alternatively be used. For example, the order of execution of the blocks may be rearranged or performed in series or parallel with each other, blocks may be changed, eliminated, and/or combined to perform method 500. Further, because method 500 is disclosed in connection with the components of FIGS. 1-4, some functions of those components will not be described in detail below.

Method 500 may start at block 502. At block 504, method 500 may include capturing a first section of an image frame at a reduced light intensity level. As noted above, the reduced light intensity level is a reduced light intensity level with respect to a maximum average light intensity level.

At block 506, method 500 includes capturing a second section of the image frame at an increased light intensity level. As noted above, the increased light intensity level is an increased light intensity level with respect to the maximum average light intensity level. In effect, the available light intensity (i.e., the different between the reduced light intensity level and the maximum average light intensity level) is shifted from use during the first section to use during the second section. In this manner, the same overall light intensity is output, while providing increased lighting during capture of the second section during which important visual information is captured. Light intensity is shifted from a section in which no important visual information is captured by the camera to a section in which there is important visual information to be captured.

At block 508, method 500 includes pausing exposure during a frame time gap. As noted above, the frame time gap enables the camera to operate at a particular frame rate, based on a delay between the capturing of a last row of a frame and the first row of a next frame.

At block 510, method 500 may include determining whether the last frame has been captured. If the vehicle continues to capture image frames (i.e., the camera remains on), the method may revert back to block 504 to capture a next frame. However, if the vehicle stops capturing frames (i.e., the vehicle turns off, or the disclosed functionality is turned off), the method then ends at block 512.

In this application, the use of the disjunctive is intended to include the conjunctive. The use of definite or indefinite articles is not intended to indicate cardinality. In particular, a reference to “the” object or “a” and “an” object is intended to denote also one of a possible plurality of such objects. Further, the conjunction “or” may be used to convey features that are simultaneously present instead of mutually exclusive alternatives. In other words, the conjunction “or” should be understood to include “and/or”. As used here, the terms “module” and “unit” refer to hardware with circuitry to provide communication, control and/or monitoring capabilities, often in conjunction with sensors. “Modules” and “units” may also include firmware that executes on the circuitry. The terms “includes,” “including,” and “include” are inclusive and have the same scope as “comprises,” “comprising,” and “comprise” respectively.

The above-described embodiments, and particularly any “preferred” embodiments, are possible examples of implementations and merely set forth for a clear understanding of the principles of the invention. Many variations and modifications may be made to the above-described embodiment(s) without substantially departing from the spirit and principles of the techniques described herein. All modifications are intended to be included herein within the scope of this disclosure and protected by the following claims.

1. A vehicle comprising:
a CMOS camera including a plurality of rows;
one or more lights configured to illuminate a field of view of the CMOS camera; and
an imaging controller configured to:
capture a plurality of image frames by, for each image frame:
exposing one or more rows of the CMOS camera at a time; and
pausing exposure during a frame time gap after capturing a last row of the CMOS camera; and
for an image frame of the plurality of image frames:
operate the one or more lights at a reduced intensity level during a first section of the image frame, wherein the reduced intensity level is lower than a maximum average intensity level; and
operate the one or more lights at an increased intensity level during a second section of the image frame, wherein the increased intensity level is higher than the maximum average intensity level, wherein the second section includes one or more rows of the CMOS camera, wherein the one or more rows comprise a subset of the plurality of rows of the CMOS camera selected based on one or more vehicle metrics.

2. The vehicle of claim 1, wherein the first section includes the frame time gap.

3. The vehicle of claim 1, wherein the first section comprises a subset of the plurality of rows of the CMOS camera including one or more of only a top row and/or bottom row of the CMOS camera.

4. The vehicle of claim 1, wherein a difference between the reduced intensity level and the increased intensity level is 5%.

5. The vehicle of claim 1, wherein the increased intensity level is more than 10 times greater than the maximum average intensity level.

6. (canceled)

7. The vehicle of claim 1, wherein the plurality of rows of the CMOS camera comprise a first subset configured to capture a shroud of the CMOS camera, and a second subset configured to not capture the shroud of the CMOS camera, and wherein the second section includes the second subset.

8. The vehicle of claim 1, wherein the imaging controller is further configured to determine a horizon position, and wherein the one or more rows comprise a subset of the plurality of rows of the CMOS camera selected based on the horizon position.

9. (canceled)

10. The vehicle of claim 1, wherein the one or more vehicle metrics comprise one or both of a geographic location and a vehicle orientation.

11. The vehicle of claim 1, wherein the imaging controller is further configured to modify a gain and an exposure time of the one or more rows of the second section of the image frame.

12. The vehicle of claim 1, wherein a combined average intensity level of the reduced intensity level during the first section and the increased intensity level during the second section is the maximum average intensity level.

13. A method of capturing images by a vehicle camera comprising:
capturing a plurality of image frames by, for each image frame:
exposing one or more rows of the vehicle camera at a time, wherein the vehicle camera is a CMOS camera, and wherein the vehicle camera includes a plurality of rows;
pausing exposure during a frame time gap after capturing a last row of the vehicle camera; and
for an image frame of the plurality of image frames:
determining a horizon position on the image frame;
operating one or more vehicle lights illuminating a field of view of the vehicle camera at a reduced intensity level during a first section of the image frame, wherein the reduced intensity level is lower than a maximum average intensity level; and
operating the one or more vehicle lights at an increased intensity level during a second section of the image frame, wherein the increased intensity level is higher than the maximum average intensity level, wherein the second section includes one or more rows of the vehicle camera, wherein the one or more rows comprise a subset of the plurality of rows of the CMOS camera selected based on the horizon position.

14. The method of claim 13, wherein the first section includes the frame time gap.

15. (canceled)

16. The method of claim 13, wherein the plurality of rows of the CMOS camera comprise a first subset configured to capture a shroud of the CMOS camera, and a second subset configured to not capture the shroud of the CMOS camera, and wherein the second section includes the second subset.

17. (canceled)

18. The method of claim 13, wherein the one or more rows comprise a subset of the plurality of rows of the CMOS camera selected based on one or more vehicle metrics.

19. The method of claim 18, wherein the one or more vehicle metrics comprise one or both of a geographic location and/or vehicle orientation.

20. The method of claim 13, further comprising modifying a gain and an exposure time of the one or more rows of the second section of the image frame.
